(19) United States
(12) Patent Application Publication
(10) Pub. No.: US 2008/0042218 A1
(43) Pub. Date: Feb. 21, 2008

(54) SEMICONDUCTOR MEMORY DEVICE

(76) Inventors: Motoshige IGARASHI, Tokyo (JP); Nobuo Tsuboi, Tokyo (JP); Toshihumi Iwasaki, Tokyo (JP); Koji Nii, Tokyo (JP); Yasumasa Tsukamoto, Tokyo (JP)

Correspondence Address: MILES & STOCKBRIDGE PC, 1751 PINNACLE DRIVE, SUITE 500, MCLEAN, VA, 22102-3833, US

(21) Appl. No.: 11/836,634

(22) Filed: Aug. 9, 2007

(30) Foreign Application Priority Data
Aug. 16, 2006 (JP) 2006-221906

(51) Int. Cl. H01L 21/8244; H01L 29/76

(52) U.S. Cl. 257/391; 257/E29.226; 257/E21.661

(57) ABSTRACT

The semiconductor memory device which can suppress that the characteristics variation of a transistor increases in connection with microfabrication is offered.

In the memory cell of the present invention, channel width of an access transistor is made larger than the channel width of a driver transistor about the relation of the channel width of an access transistor and a driver transistor. That is, since the access transistor can make channel area increase from the driver transistor designed with the minimum designed size, it becomes possible to suppress the increase in the characteristics variation of an access transistor.

### CROSS-REFERENCE TO RELATED APPLICATION

The present application claims priority from Japanese patent application No. 2006-221906 filed on Aug. 16, 2006, the content of which is hereby incorporated by reference into this application.

### FIELD OF THE INVENTION

The present invention relates to the layout of a CMOS type SRAM memory cell among semiconductor memory devices.

### DESCRIPTION OF THE BACKGROUND ART

In recent years, the importance of digital signal processing which processes a lot of data like a sound and a picture at high speed is becoming high with the spread of portable terminal equipment. As a semiconductor memory device mounted in such portable terminal equipment, SRAM in which high-speed access processing is possible occupies the important position.

Especially in recent years, it is in the tendency which also makes bit capacity of SRAM into large capacity with large-scale-izing of the system mounted in a semiconductor chip. In order to accept the request at the side of such a system, the size of the memory cell which forms SRAM is wanted to be reduced more.

In order to reduce memory cell size, it is effective to use an MOS transistor with smaller channel width, but by such a pattern with small size, the characteristics variation of a transistor becomes large easily. The method which adjusts the channel width of a transistor and suppresses process variation is disclosed by Patent Reference 1.

FIG. 17 is a drawing explaining the case where characteristics variation increases based on changes of the minimum designed size in a P channel MOS transistor and an N channel MOS transistor.

It is shown that the variation in a transistor increases in inverse proportion to the square root of the product (channel area) of the channel length and channel width of a transistor as shown in FIG. 17. That is, as a generation progresses like the minimum designed size is 130 nm, 90 nm, 65 nm, that is, as the channel area of the transistor accompanying microfabrication is reduced, the characteristics variation of a transistor will become much more remarkable.

[Patent Reference 1] Japanese Unexamined Patent Publication No. 2003-115551

### SUMMARY OF THE INVENTION

The present invention is made in order to solve the above problems. It aims at offering the semiconductor memory device which can suppress that the characteristics variation of a transistor increases in connection with microfabrication.

A semiconductor memory device concerning this invention comprises a memory array which has a plurality of memory cells arranged at matrix form a word line formed corresponding to a memory cell row, and a bit line pair formed corresponding to a memory cell column. The each memory cell includes a first inverter including a first N-channel MOS transistor and a first P-channel MOS transistor, a second inverter including a second N-channel MOS transistor and a second P-channel MOS transistor, and a third and a fourth N-channel MOS transistor. An input node of the first inverter is connected to an output node of the second inverter so that the first inverter and the second inverter may form a flip-flop. An input node of the second inverter is connected to an output node of the first inverter, the third N-channel MOS transistor is connected between one side of a corresponding bit line pair, and an input node of the second inverter, and a gate is electrically combined with a corresponding word line. The fourth N-channel MOS transistor is connected between the other of the corresponding bit line pair, and an input node of the first inverter, and a gate is electrically combined with the corresponding word line. The each memory cell includes a first active region that forms the first and the third N-channel MOS transistor formed over a substrate, a second active region that forms the second and the fourth N-channel MOS transistor, and the first to the fourth polysilicon wiring that are formed respectively corresponding to the first to the fourth N-channel MOS transistor, and that are located so that a corresponding active region may be crossed, and form the channel region specified with channel length and channel width. In the first active region, the third N-channel MOS transistor is designed more greatly than at least one of the channel length and channel width of the first N-channel MOS transistor, and threshold value voltage of the first N-channel MOS transistor is designed low rather than the third N-channel MOS transistor originating in the channel length and channel width. In the second active region, the fourth N-channel MOS transistor is designed more greatly than at least one side of the channel length and channel width of the second N-channel MOS transistor. Threshold value voltage of the second N-channel MOS transistor is designed low rather than the fourth N-channel MOS transistor originating in the channel length and channel width.

Another semiconductor memory device concerning this invention comprises a memory array which has a plurality of memory cells arranged at matrix form, and a peripheral circuit for interior-action control of the memory array. The each memory cell formed by a first inverter including a first N-channel MOS transistor and a first P-channel MOS transistor, and a second inverter including a second N-channel MOS transistor and a second P-channel MOS transistor connected so that a flip-flop may be formed with the first inverter includes a first and a second active region that forms the first and the second N-channel MOS transistor, respectively, and a third and a fourth active region that forms the first and the second P-channel MOS transistor which are formed over a substrate in order to form the first and the second inverter, a first polysilicon wiring that is located so that the first and the third active region may be crossed, and forms a gate region of the first N-channel MOS transistor and P-channel MOS transistor, and a second polysilicon wiring that is located so that the second and the fourth active region may be crossed, and forms a gate region of the second N-channel MOS transistor and P-channel MOS transistor. An impurity quantity implanted into a gate region of the first and the second P-channel MOS transistor is set up less than an impurity quantity implanted into a gate region of the P-channel MOS transistor formed in the peripheral circuit.

Another semiconductor memory device concerning this invention comprises a memory array which has a plurality of memory cells arranged at matrix form, and a peripheral circuit for interior-action control of the memory array. The each memory cell includes a plurality of MOS transistors which form a first inverter and a second inverter connected with the first inverter so that a flip-flop may be formed. The each MOS transistor includes an active region which has an impurity implantation region formed over a substrate. An impurity quantity implanted into an impurity implantation region of each of the MOS transistor of the memory array is set up less than an impurity quantity implanted into an impurity implantation region of a MOS transistor formed in the peripheral circuit.

Further another semiconductor memory device concerning this invention comprises a memory array which has a plurality of memory cells arranged at matrix form, and a peripheral circuit for interior-action control of the memory array. The each memory cell includes a plurality of MOS transistors which form a second inverter connected with a first inverter so that a flip-flop may be formed with the first inverter. The each MOS transistor includes an active region which has an impurity implantation region formed over a substrate. The peripheral circuit includes a first group's MOS transistor group which has a first threshold value voltage, and a second group's MOS transistor group which has a second threshold value voltage higher than the first threshold value voltage. An impurity quantity implanted into an impurity implantation region of each of the MOS transistor of the memory array is set up few rather than an impurity quantity implanted into an impurity implantation region of the first group's MOS transistor group formed in the peripheral circuit, and it is set up like an impurity quantity implanted into an impurity implantation region of the second group's MOS transistor group.

In the first active region, as for the semiconductor memory device concerning the present invention, the third N-channel MOS transistor is designed more greatly than at least one side of the channel length and channel width of the first N-channel MOS transistor, and in the second active region, the fourth N-channel MOS transistor is designed more greatly than at least one side of the channel length and channel width of the second N-channel MOS transistor. Channel area can be enlarged by designing channel length and channel width greatly by this regarding the third and fourth N-channel MOS transistor, and it can suppress that the characteristics variation of a transistor increases in connection with microfabrication.

As for another semiconductor memory device concerning the present invention, to the first polysilicon wiring that forms the gate region of the first N-channel MOS transistor and the P-channel MOS transistor, the impurity quantity implanted into the gate region of the first P-channel MOS transistor is set up less than the impurity quantity implanted into the gate region of the P-channel MOS transistor formed in a peripheral circuit. Hereby, the influence of the gate mutual diffusion generated in the first polysilicon wiring can be inhibited, and it can suppress that the characteristics variation of the first N-channel MOS transistor increases.

As for another semiconductor memory device concerning the present invention, by setting up the impurity quantity implanted into the impurity implantation region of each MOS transistor of a memory array less than the impurity quantity implanted into the impurity implantation region of the MOS transistor formed in a peripheral circuit, it can suppress that the characteristics variation of each MOS transistor of a memory array increases.

As for another semiconductor memory device concerning the present invention, about the impurity quantity implanted into the impurity implantation region of each MOS transistor of a memory array, by setting up few rather than the impurity quantity implanted into the impurity implantation region of the first group's MOS transistor group formed in a peripheral circuit, and setting up like the impurity quantity implanted into the impurity implantation region of the second group's MOS transistor group, while suppressing that the characteristics variation of each MOS transistor of a memory array increases, by applying a step being the same as that of the step implanted into the second group's MOS transistor group to a memory array by setting up like the impurity quantity of the MOS transistor group of the second group of a peripheral circuit, a process number is not made to increase and cost can be made low.

### BRIEF DESCRIPTION OF THE DRAWINGS

FIG. 1 is a drawing which illustrates roughly the entire configuration of the semiconductor memory device according to Embodiment 1 of the present invention;

FIG. 2 is a drawing explaining the structure of memory cell MC according to Embodiment 1 of the present invention;

FIG. 3 is a drawing explaining the plane layout of the memory cell according to Embodiment 1 of the present invention;

FIGS. 4A and 4B are drawings explaining the relation between channel width and the threshold value voltage of a transistor;

FIG. 5 is a drawing explaining the layout structure of memory cell MC according to the modification of Embodiment 1 of the present invention;

FIGS. 6A and 6B are drawings explaining the relation between channel length and the threshold value voltage of a transistor;

FIG. 7 is a drawing explaining the layout structure according to modification 2 of Embodiment 1 of the present invention;

FIG. 8 is a drawing explaining gate mutual diffusion;

FIG. 9 is a section structure picture of the driver transistor which shares a polysilicon gate with the load transistor of a SRAM memory cell;

FIG. 10 is a drawing explaining the impurity concentration implanted into the transistor formed in the memory array and peripheral circuit in Embodiment 2 of the present invention;

FIGS. 11A to 11E are drawings explaining a part of step in the case of forming the transistor of a memory array and a peripheral circuit;

FIG. 12 is a drawing explaining the impurity concentration implanted into the transistor formed in the memory array and peripheral circuit according to modification 1 of Embodiment 2 of the present invention;

FIG. 13 is a drawing explaining channel implantation amount and the characteristics variation of a transistor;

FIGS. 14A and 14B are drawings explaining the impurity concentration implanted into the transistor formed in the memory array and peripheral circuit according to modification 2 of Embodiment 2 of the present invention;

FIG. 15 is a schematic diagram of word line driver WDV and assistant circuit PD according to Embodiment 3 of the present invention;

FIG. 16 is a drawing showing the signal wave form of the main nodes at the time of read-out and the writing of data at the time of using pulldown element PD shown in FIG. 15; and

FIG. 17 is a drawing explaining the case where characteristics variation increases based on changes of the minimum designed size in a P channel MOS transistor and an N channel MOS transistor.

### DETAILED DESCRIPTION OF THE PREFERRED EMBODIMENTS

Hereafter, it explains in detail, referring to a drawing for this embodiment of the invention. The same reference is given to the same or the corresponding portion in a drawing, and the explanation is not repeated.

### Embodiment 1

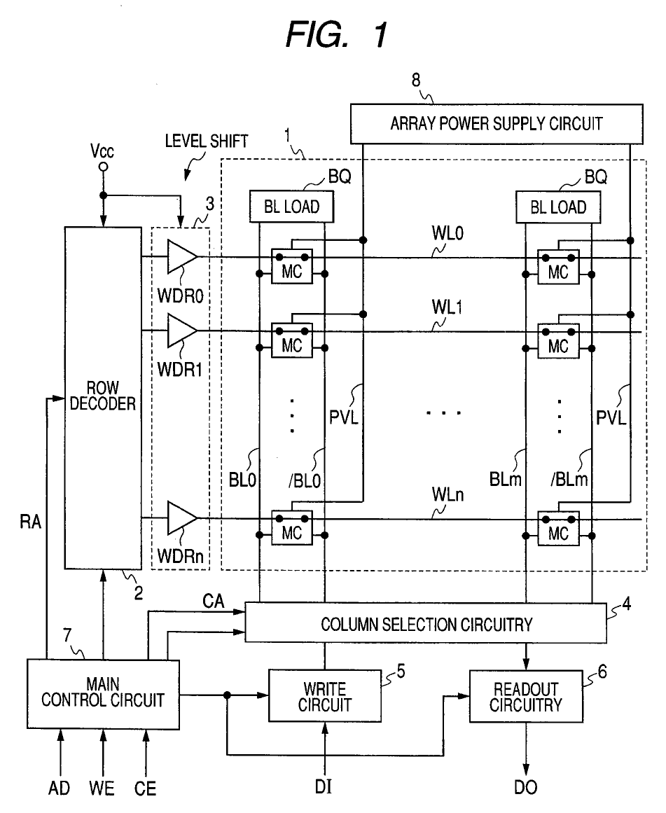

FIG. 1 is a drawing which illustrates roughly the entire configuration of the semiconductor memory device according to Embodiment 1 of the present invention.

With reference to FIG. 1, the semiconductor memory device according to Embodiment 1 of the present invention includes memory array 1 by which accumulation arrangement of memory cell MC is done at matrix form. Memory cell MC is arranged by (n+1) row (m+1) column in memory array 1. Corresponding to each row of memory cell MC, word lines WL0-WLn are located, and memory cell MC is connected to the word line of a corresponding row, respectively. Corresponding to each column of memory cell MC, bit line pair BL0,/BL0-BLm,/BLm are located. Memory cell MC is a static type memory cell, as explained in detail later, and complementary data is transmitted to complementary bit line pair BLi,/BLi(i=0˜m).

Corresponding to the pair of each of bit line BL0,/BL0-BLm,/BLm, bit line load (BL load) BQ is formed. This bit line load BQ does pull-up of the electric potential of a corresponding bit line at the time of data read-out, and supplies the column current at the time of data read-out to a memory cell.

In order that the addressed word line is driven to a selective state in memory array 1, row decoder 2 which generates a row selection signal according to address signal RA, and word line drive circuit 3 which drives the word line chosen based on the row selection signal from row decoder 2 to a selective state are formed.

Row decoder 2 operates considering supply voltage VDD as operation power voltage, decodes row address RA, and generates a row selection signal.

Word line driver circuit 3 is formed corresponding to each of word lines WL0-WLn, and includes word line driver WDR0-WDRn which drive a corresponding word line to a selective state according to the row selection signal from row decoder 2.

Word line driver WDR0-WDRn operate considering supply voltage VDD as operation power voltage respectively, and activate a corresponding word line selectively.

Semiconductor memory device 1 further includes column selection circuitry 4 which chooses the bit line pair corresponding to selection columns according to column address CA, writing circuit 5 which transmits a write data to the bit line pair corresponding to the column chosen by column selection circuitry 4 at the time of data write, read-out circuit 6 which detects and amplifies the data from the bit line pair corresponding to the column chosen by column selection circuitry 4 at the time of data read-out, and generates read-out data, and main control circuit 7 which generates and outputs row address RA, column address CA, and a control signal required for each operation according to address signal AD, write-in indication signal WE, and chip enable signal CE from the outside.

Main control circuit 7 generates a word line activation timing signal and a column selection timing signal, and specifies the operation timing and the operating sequence of row decoder 2 and column selection circuitry 4.

Writing circuit 5 amends an internal write data according to write-data DI from the outside including an input buffer and a write-in drive circuit at the time of data write. Including a sense amplifier circuit and an output buffer, at the time of data read-out, read-out circuit 6 does further buffer processing of the inside data by which detection amplification was done in the sense amplifier circuit by an output buffer, and generates external read-out data DO.

Writing circuit 5 and read-out circuit 6 can also perform writing and read-out of the data of two or more bit width, respectively. It is also possible to have structure for which memory array 1 corresponds to the input output data which is 1 bit, and writing circuit 5 and read-out circuit 6 perform the input and output of 1-bit data, respectively. Generally, at the time of writing/read-out of a data bit, writing circuit 5 and read-out circuit 6 are formed to memory array 1 shown in FIG. 1 corresponding to each data bit.

The array supply voltage from array power supply circuit 8 is supplied to the high side power node of memory cell MC via array power supply line PVL. This array power supply line PVL is shown that it divides and locates for every memory cell column in FIG. 1. It is also possible to supply array supply voltage common to these array power supply lines PVL from array power supply circuit 8. That is, array power supply line PVL may have the structure arranged in the shape of a mesh by which interconnection is done to a row direction and a column direction.

The array supply voltage from array power supply circuit 8 is set as the same voltage level as that of supply voltage VDD supplied to word line driver WDR in this embodiment and the following embodiments. However, the present invention is applicable even if array supply voltage, and the supply voltage supplied to a word line drive circuit are different voltage levels. Array power supply circuit 8, and the circuit which supplies supply voltage to peripheral circuits, such as word line drive circuit 3, may be arranged independently.

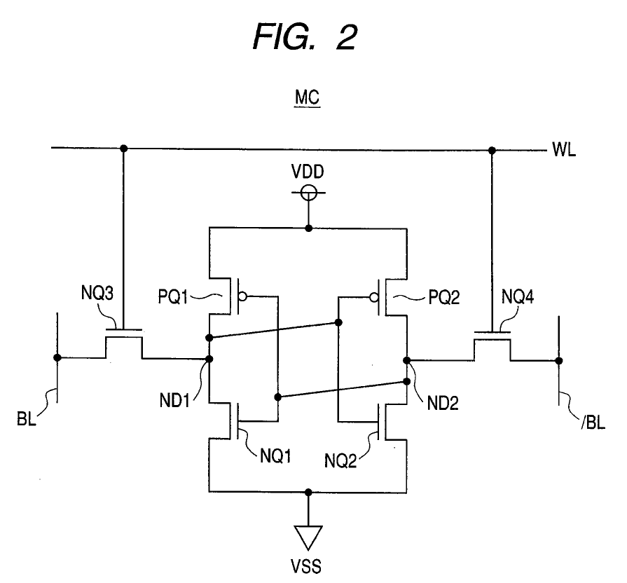

FIG. 2 is a drawing explaining the structure of memory cell MC according to Embodiment 1 of the present invention. With reference to FIG. 2, memory cell MC according to Embodiment 1 of the present invention includes P channel MOS transistor PQ1 by which it is formed between high side supply voltage VDD and memory node ND1, and the gate is electrically combined with memory node ND2, N channel MOS transistor NQ1 by which it is electrically combined with memory node ND1 and low side supply voltage VSS, and the gate is electrically combined with memory node ND2, P channel MOS transistor PQ2 which is arranged between high side supply voltage VDD and memory node ND2, and by which the gate is electrically combined with memory node ND1, N channel MOS transistor NQ2 which is arranged between low side supply voltage VSS and memory node ND2, and by which the gate is electrically combined with memory node ND1, and N channel MOS transistor NQ3 and NQ4 which combine memory nodes ND1 and ND2 with bit line BL and /BL according to the voltage on word line WL, respectively.

In the structure of memory cell MC shown in this FIG. 2, P channel MOS transistor PQ1 and N channel MOS transistor NQ1 form a CMOS inverter, P channel MOS transistor PQ2 and N channel MOS transistor NQ2 form a CMOS inverter, and cross linking of the input and output of these inverters is done, and they form an inverter latch. And complementary data of each other is held at memory nodes ND1 and ND2.

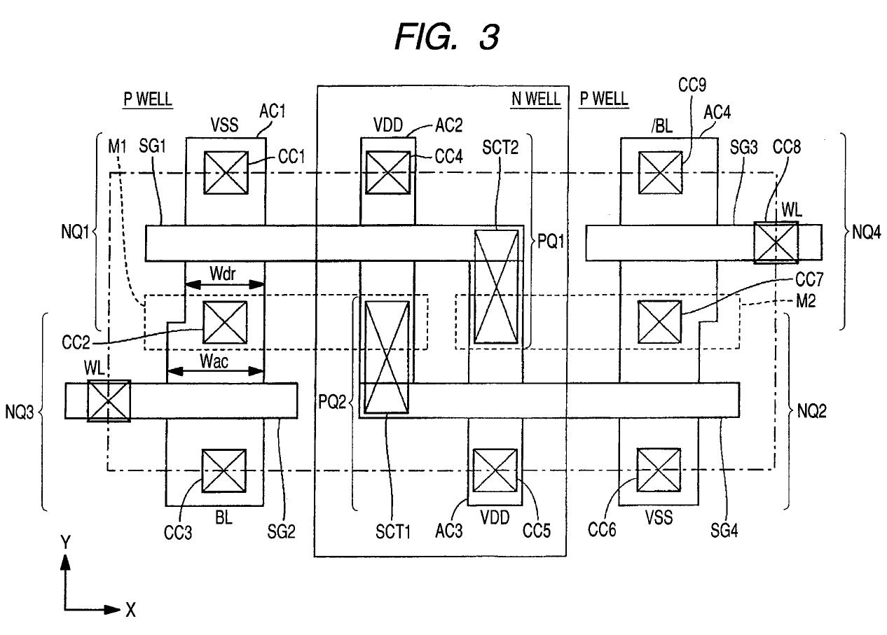

FIG. 3 is a drawing explaining the plane layout of the memory cell according to Embodiment 1 of the present invention.

With reference to FIG. 3, memory cell MC includes active regions AC2 and AC3 formed in N well region, and active regions AC1 and AC4 formed in each of P well region of the both sides of this N well region.

P channel MOS transistor PQ1 and PQ2 which are load transistors, respectively are formed in active regions AC2 and AC3. In active regions AC1 and AC4, N channel MOS transistors NQ1 and NQ2 which are drive transistors respectively, and N channel MOS transistors NQ3 and NQ4 which are access transistors are formed.

Active region AC1 has a region (narrow width region) whose width of the X direction is Wdr, and Wac (wide width region) whose width of the X direction is wider or larger than Wdr. Polysilicon wiring SG1 is located so that the narrow width region of active region AC1 may be crossed to the X direction, and polysilicon wiring SG2 is located so that a wide width region may be crossed to the X direction. Polysilicon wiring SG2 forms the gate of access transistor NQ3.

In the end portion of the Y direction of the narrow width region of active region AC1, contact CC1 for receiving source voltage VSS of the low side is formed, and contact CC3 for electrically combining with bit line BL is formed in the end portion of the Y direction of a wide width region. In active region AC1, in the boundary part of a wide width region and a narrow width region, contact CC2 is formed and it is electrically combined with shared contact SCT1 using the upper metal wiring M1.

In active region AC2, contact CC4 for receiving high side supply voltage VDD in the end portion of the Y direction is formed, and shared contact SCT1 is located at the other side of it. An end is combined with active region AC2 and, as for this shared contact SCT1, other side end is combined with polysilicon wiring SG4 located so that active regions AC3 and AC4 may be crossed to the X direction. This shared contact SCT1 is provided with both the functions of contact, and a middle connection wiring.

In active region AC3, shared contact SCT2 is formed in the one side end part of the Y direction. Polysilicon wiring SG1 located to the X direction so that active regions AC1 and AC2 may be crossed, and the one side end part of active region AC3 are electrically combined via this shared contact SCT2. Polysilicon wiring SG1 forms the common gate of load transistor PQ1 and driver transistor NQ1.

In the other side end part of active region AC3, contact CC5 for receiving supply voltage VDD is formed.

In active region AC4, contact CC9 electrically combined with a bit line/BL in the end portion of the Y direction of a wide width region is formed, and polysilicon wiring SG3 is located so that it may cross to the X direction. Polysilicon wiring SG3 forms the gate of access transistor NQ4. In active region AC4, in the boundary part of a wide width region and a narrow width region, contact CC7 is formed and it is electrically combined with shared contact SCT2 using the upper metal wiring M2.

In active region AC4, polysilicon wiring SG4 is formed so that a narrow width region may be crossed to the X direction, and in the end portion of this narrow width region, contact CC6 for electrically connecting with supply voltage VSS at the side of a low is formed. Polysilicon wiring SG4 forms the common gate of load transistor PQ2 and driver transistor NQ2.

Generally, in the relation between a driver transistor and an access transistor, in order to enlarge driving ability of a driver transistor, the case where the length of the X axial direction of an active region, i.e., channel width, is made widely or larger than an access transistor is common. However, in this example, it is opposite, and the channel width of the access transistor is designed to be larger than a driver transistor (Wac>Wdr). This reason is explained below.

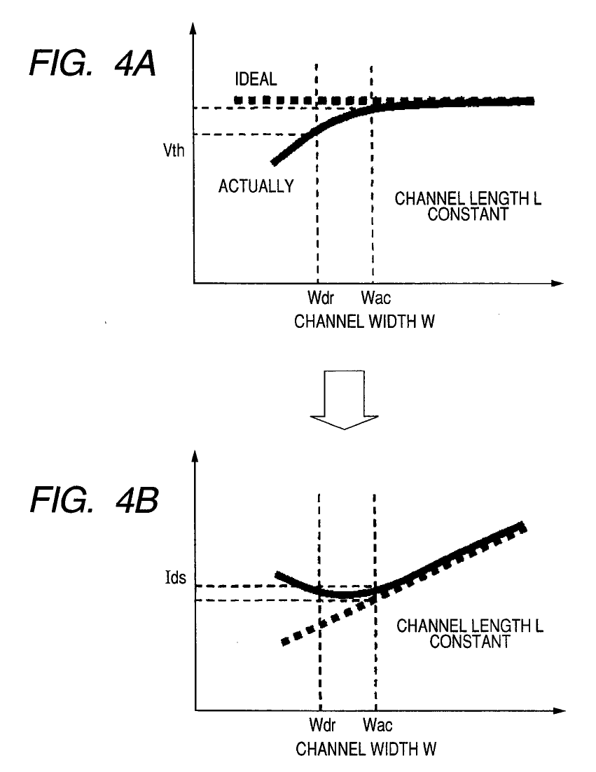

FIGS. 4A and 4B are drawings explaining the relation between channel width, and the threshold value voltage of a transistor. FIG. 4A is a drawing which illustrates change of threshold value voltage Vth of a transistor at the time of changing channel width W when channel length L is constant.

As shown in FIG. 4A, the more it does microfabrication of the channel width W and narrows the width, the more the reverse narrow characteristics that threshold value voltage more nearly actual falls than the threshold value voltage designed as an ideal appear.

Therefore, as shown in FIG. 4B, current Ids between drain sources of a transistor tends to increase as channel width W narrows.

The transistor has been designed in a conventional SRAM memory cell so that it becomes a value in which these reverse narrow characteristics do not appear, i.e., the channel width from which the threshold value voltage of an ideal is obtained, generally. However, while the minimum designed size becomes still severer and the microfabrication of a transistor is required in recent years, when designing a transistor, it is becoming a situation where the channel width of a transistor must be designed in the region in which these reverse narrow characteristics appear.

Therefore, when these reverse narrow characteristics are taken into consideration, as for memory cell MC according to Embodiment 1 of the present invention, by making channel width of an access transistor larger than a driver transistor in the relation of the channel width of an access transistor and a driver transistor, it becomes possible to form a difference in the driving ability of a transistor. Namely, by designing an access transistor and a driver transistor with the layout pattern concerned, it becomes possible to make driving ability of a driver transistor larger than the driving ability of an access transistor, and to maintain, the input output characteristics, i.e., the data holding characteristics, of an inverter circuit.

Or when the driving ability of a driver transistor does not become larger than the driving ability of an access transistor, by increasing threshold value voltage Vth by performing channel implantation for threshold value adjustment to an access transistor, it is also possible to make driving ability of a driver transistor larger than the driving ability of an access transistor.

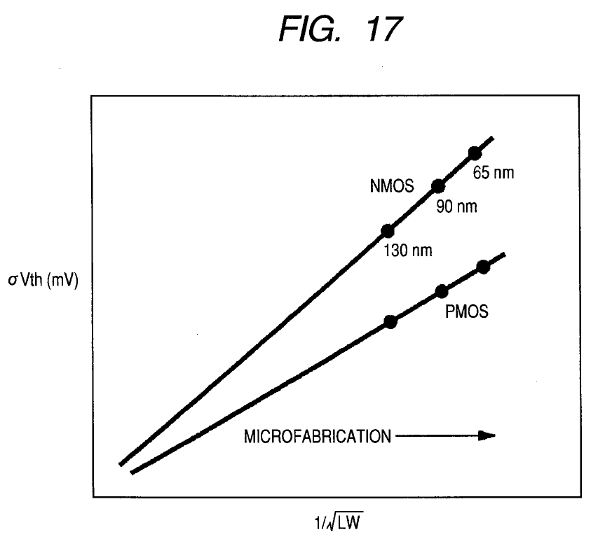

And in this structure, it is the structure which enlarged channel width Wac of active region AC1 which forms an access transistor to channel width Wdr of active region AC1 which forms the driver transistor located according to the minimum designed size. That is, the access transistor can make channel area increase from the driver transistor designed with the minimum designed size. That is, since the area of LW can be made to increase, it becomes possible to suppress the increase in the characteristics variation of an access transistor, as FIG. 17 explained.

### Modification 1 of Embodiment 1

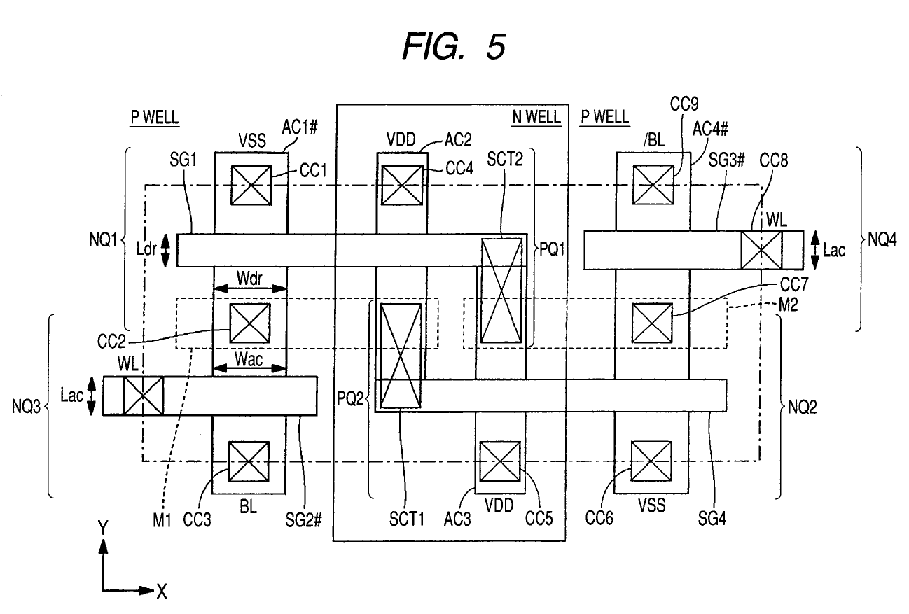

FIG. 5 is a drawing explaining the layout structure of memory cell MC according to modification 1 of Embodiment 1 of the present invention.

A different point as compared with the layout explained by FIG. 3 differs in that active region AC4 was replaced by active region AC4# while replacing active region AC1 by active region AC1#.

Active region AC1# makes the same length channel width with driver transistors NQ1 and NQ3. Regarding the channel length of polysilicon gate SG1 and polysilicon gate SG2#, polysilicon gate SG2# of an access transistor is made longer than polysilicon gate SG1, and it is located.

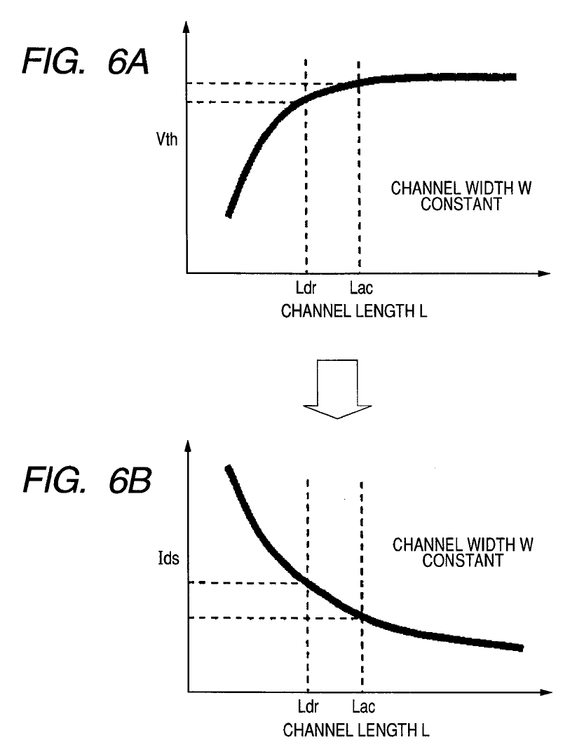

FIG. 6A is a drawing explaining the relation between channel length, and the threshold value voltage of a transistor. FIG. 6A is a drawing explaining change of threshold value voltage Vth of a transistor at the time of changing channel length L, when channel width W is constant.

As shown in FIG. 6A, the more it does microfabrication of the channel length L and shortens the length, the more the short channel characteristics that actual threshold value voltage falls rather than the threshold value voltage designed as an ideal appear.

Therefore, as shown in FIG. 6B, current Ids between drain sources of a transistor is in the tendency which increases as channel length L becomes short.

The transistor has been designed in a conventional SRAM memory cell to become a value in which short channel characteristics do not appear as well as reverse narrow characteristics, i.e., to become the channel length by which the threshold value voltage of an ideal is got, generally. However, while the minimum designed size becomes still severer and the microfabrication of a transistor is required in recent years, it is becoming a situation which must be designed in the region in which these short channel characteristics appear when designing the channel length of a transistor.

Therefore, in memory cell MC according to the modification of Embodiment 1 of the present invention, when these short channel characteristics are taken into consideration, by making channel length of an access transistor longer i.e., larger than a driver transistor, in the relation of the channel length of an access transistor and a driver transistor, it becomes possible to form a difference in the driving ability of a transistor. Namely, by designing an access transistor and a driver transistor with the layout pattern concerned, it becomes possible to make driving ability of a driver transistor larger than the driving ability of an access transistor, and to maintain, the input output characteristics, i.e., the data holding characteristics, of an inverter circuit.

And in this structure, it is the structure which enlarged channel length Lac of active region AC1 which forms an access transistor to channel length Ldr of active region AC1 which forms a driver transistor located according to the minimum designed size. That is, the access transistor can make channel area increase from the driver transistor designed with the minimum designed size. That is, since the area of LW can be made to increase, it becomes possible to suppress the increase in the characteristics variation of an access transistor, as FIG. 17 explained.

### Modification 2 of Embodiment 1

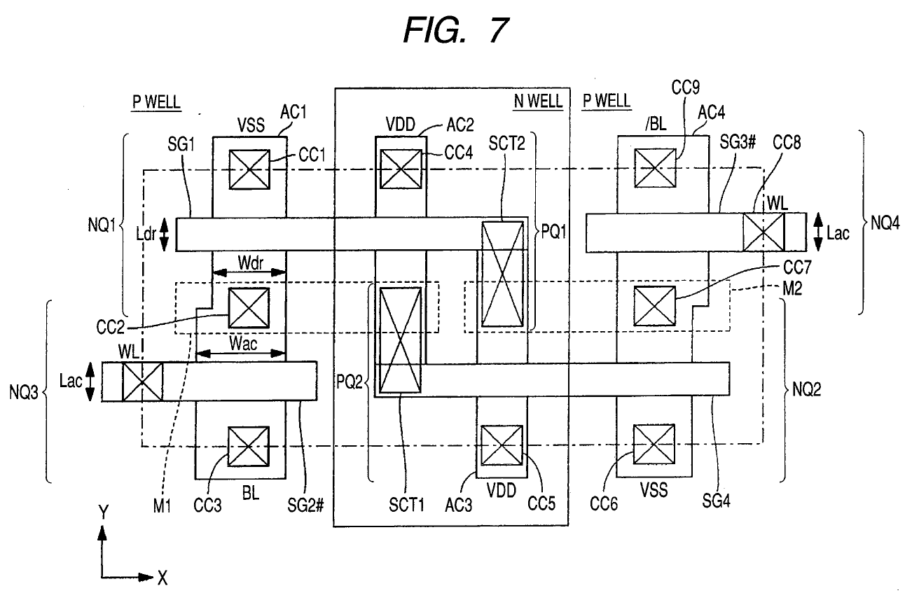

FIG. 7 is a drawing explaining the layout structure according to modification 2 of Embodiment 1 of the present invention.

Here, the method which combined the layout pattern of FIG. 3 and FIG. 5 mentioned above is explained. Concretely, channel width of an access transistor is enlarged in the relation between the channel width of an access transistor, and the channel width of a driver transistor. In the relation between the channel length of an access transistor, and the channel length of a driver transistor, it is the structure which enlarges channel length of an access transistor.

This considers reverse narrow characteristics and short channel characteristics as the FIG. 4 and FIG. 6 which were mentioned above having explained in memory cell MC according to modification 2 of Embodiment 1 of the present invention. By making channel width of an access transistor larger than a driver transistor in the relation of the channel width of an access transistor and a driver transistor, a difference is formed in the driving ability of a transistor. By making channel length of an access transistor larger than a driver transistor in the relation of the channel length of an access transistor and a driver transistor, it becomes possible to form a difference in the driving ability of a transistor.

Namely, by designing an access transistor and a driver transistor with the layout pattern concerned, it becomes possible to make driving ability of a driver transistor larger than the driving ability of an access transistor, and to maintain, the input output characteristics, i.e., the data holding characteristics, of an inverter circuit.

And in this structure, it is the structure which enlarged channel width Wac and channel length Lac of active region AC1 which form an access transistor to channel width Wdr and channel length Ldr of active region AC1 which forms a driver transistor which were located according to the minimum designed size. Namely, the access transistor can make channel area able to increase from the driver transistor designed with the minimum designed size, namely, can make the area of LW increase. It becomes possible to suppress the increase in the characteristics variation of a transistor, as FIG. 17 explained.

### Embodiment 2

In above-mentioned Embodiment 1, by making channel area LW of an access transistor larger than the driver transistor designed with the minimum designed size, it explained the method which suppresses the increase in the characteristics variation of a transistor. The method which improves the characteristics variation of the transistor accompanying gate mutual diffusion in Embodiment 2 of the present invention is explained.

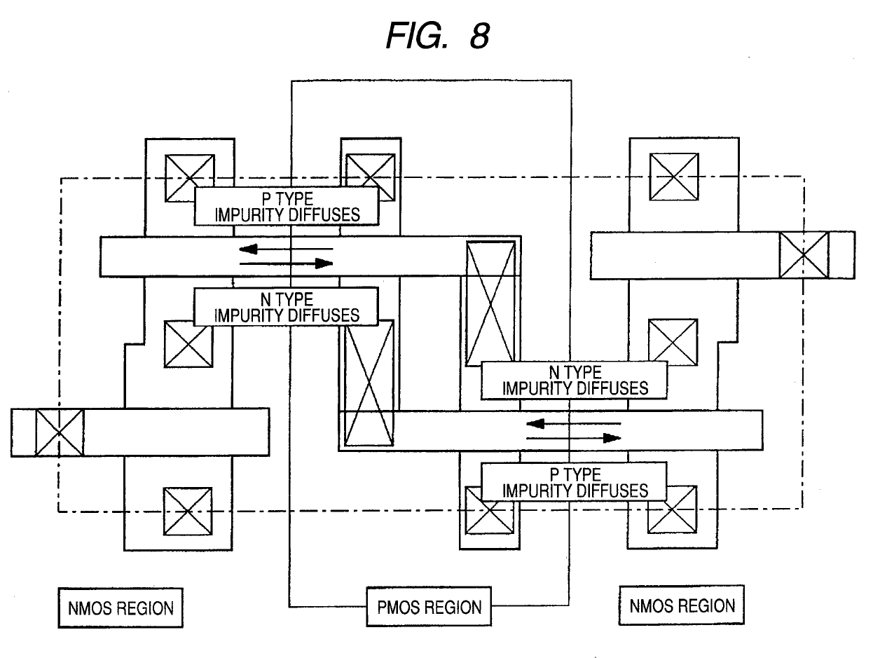

FIG. 8 is a drawing explaining gate mutual diffusion. Generally, an N type and P type impurity is implanted into the NMOS region which forms an N channel MOS transistor, and the PMOS region which forms a P channel MOS transistor at each. However, since the gate of a driver transistor and the gate of a load transistor are the structures that a gate is shared by the common polysilicon gate as shown in FIG. 8, PN boundary part exists within a polysilicon gate electrode.

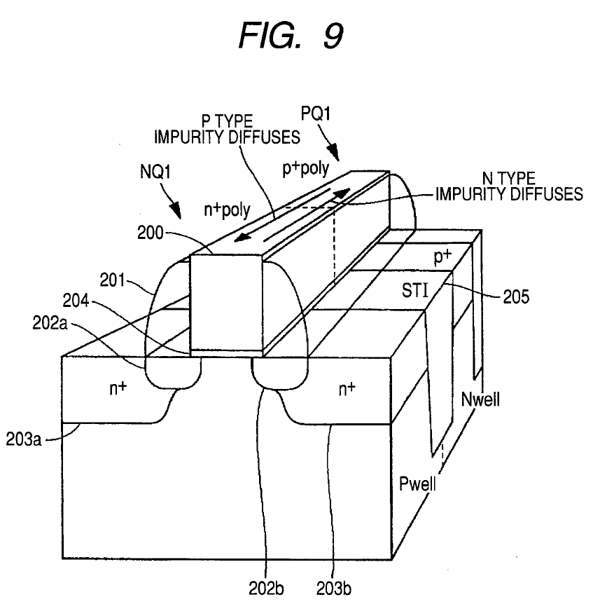

FIG. 9 is a section structure picture of the driver transistor which shares a polysilicon gate with the load transistor of a SRAM memory cell.

Transistor NQ1 which is a driver transistor is explained with reference to FIG. 9. Transistor NQ1 is formed on P well (Pwell). Oxide film 204 accumulates, polysilicon gate 200 is formed on it, and a gate region is formed. Silicide wall 201 which forms the wall part of polysilicon gate 200 is formed on P well. A source/drain region is formed by implanting an N type impurity to P well. To the outside area of silicide wall 201, an N type impurity with high concentration is implanted, and first impurity layers 203a and 203b corresponding to a source/drain region are formed. An impurity with low concentration is implanted into the lower area of silicide wall 201, and second impurity layers 202a and 202b are formed in it. And about polysilicon gate 200, the impurity of an N type is implanted to the region (N+poly) at the side of transistor NQ1, and the impurity of a P type is implanted to the region (P+poly) at the side of transistor PQ1.

The electric field near a source/drain is suppressed with the impurity with low concentration formed in the lower area of silicide wall 201. It becomes possible to lower resistance of a source/drain region with the impurity with high concentration implanted to the outside area.

In FIG. 9, the structure in which STI205 which separates an element is formed between transistor NQ1 and transistor PQ1, and polysilicon gate 200 is shared also in load transistor PQ1 is shown.

In a manufacturing process, the phenomenon in which the P type impurity and N type impurity which were implanted into the gate do mutual diffusion in PN boundary part in the polysilicon gate mentioned above since various heat treatment was applied occurs.

Therefore, when the gate gap of a driver transistor and a load transistor is short, and like especially a SRAM memory cell, a driver transistor and a load transistor are the structures that a gate is shared by the common polysilicon gate, about the gate of a driver transistor and a load transistor, the rise and variation of threshold value voltage by the formation of gate depletion according to gate mutual diffusion may occur.

It does not connect with a load transistor, PN boundary part does not exist at a gate, and an access transistor is considered that there is little influence of mutual diffusion.

Especially in Embodiment 2 of the present invention, the method which suppresses the increase in the characteristics variation accompanying the gate mutual diffusion of a driver transistor and a load transistor in a SRAM memory cell is explained.

When a driver transistor is compared with a load transistor as for the case of a SRAM memory cell and stability of operation is secured on the other hand, it is more desirable on an operating characteristic to improve the characteristics variation of a driver transistor than on a load transistor.

Therefore, in Embodiment 2 of the present invention, by designing so that the polysilicon gate of a driver transistor cannot be easily influenced by the P type impurity implanted into the polysilicon gate of a load transistor, the characteristics variation of a driver transistor with a strong operating characteristic dependence is reduced.

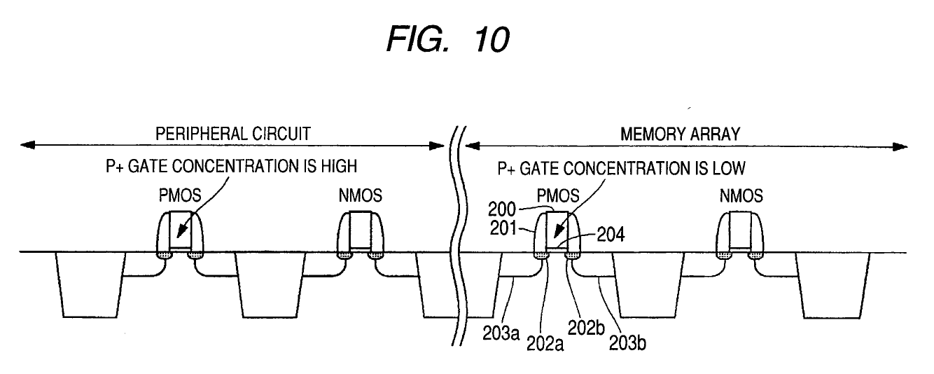

FIG. 10 is a drawing explaining the impurity concentration implanted into the transistor formed in the memory array and peripheral circuit in Embodiment 2 of the present invention.

The P channel MOS transistor and N channel MOS transistor of the SRAM memory cell by which accumulation arrangement is done with reference to FIG. 10 here at a memory array, and the P channel MOS transistor and N channel MOS transistor which form peripheral circuit, that is, the circuit for controlling the interior action of a memory array concretely are shown.

Here, the P type impurity implanted into the polysilicon gate of the P channel MOS transistor of a memory array is adjusted so that it may become less than the polysilicon gate of the P channel MOS transistor of a peripheral circuit.

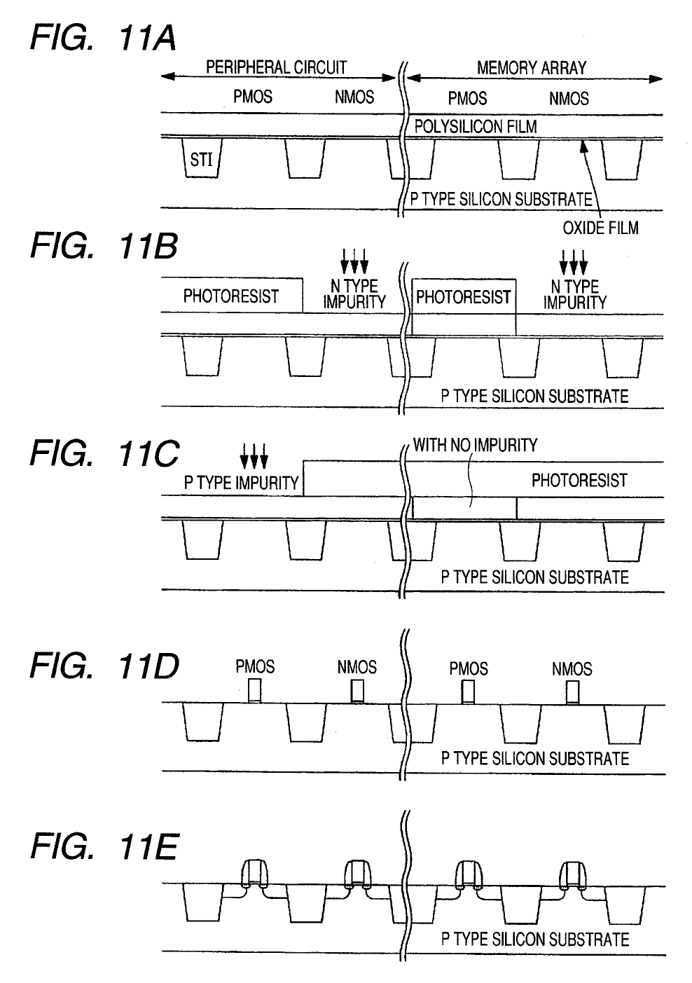

FIGS. 11A to 11F are drawings explaining a part of step in the case of forming the transistor of a memory array and a peripheral circuit.

The case where an oxide film is formed on a p type silicon substrate, and the polysilicon film is formed on it is shown in FIG. 11A. It omits here in order to simplify explanation about N well (Nwell) region and P well (Pwell) region.

In order to form the polysilicon gate of an N channel MOS transistor, resist of the formation area of a P channel MOS transistor is done to FIG. 11B next, and the case where an N type impurity is implanted is shown. Concretely, implantation of the phosphorus (P) of about 4 E+15˜6 E+15 atoms/cm² is done to the polysilicon gate of an N channel MOS transistor.

Next, in order to form the polysilicon gate of the P channel MOS transistor of a peripheral circuit in FIG. 11C, resist of the formation area of an N channel MOS transistor and the formation area of a P channel MOS transistor of a memory array is done, and a P type impurity is implanted. Concretely, implantation of the boron (B) of about 2 E+15˜4 E+15 atoms/cm² is done to the polysilicon gate of a P channel MOS transistor. In this case, since the polysilicon gate of the P channel MOS transistor of a memory array is covered with resist, a P type impurity is not implanted.

To FIG. 11D, after that, the case where a gate electrode pattern is left by a lithography process, and the polysilicon gate by etching is formed is shown.

Here, a P type impurity with low concentration is implanted to the source/drain region of a P channel MOS transistor, and the first impurity layer is formed. Concretely, a mask is covered to regions other than the P channel MOS transistor of a memory array. Implantation of the boron or boron fluoride (B or BF₂+) of about 1 E+14˜5 E+14 atoms/cm² is done to the first impurity layer that forms the source/drain region of the P channel MOS transistor of a memory array. Implantation of the boron or boron fluoride (B or BF₂+) of about 1 E+14˜5 E+14 atoms/cm² will be done also to the polysilicon gate which forms the gate region of the P channel MOS transistor of a memory array in this case.

Next, a mask is covered to regions other than a P channel MOS transistor of a peripheral circuit. Implantation of the boron or boron fluoride (B or BF₂+) of about 1 E+14˜5 E+14 atoms/cm² is done to the first impurity layer that forms the source/drain region of the P channel MOS transistor of a peripheral circuit. Implantation of the boron or boron fluoride (B or BF₂+) of about 1 E+14˜5 E+14 atoms/cm² will be done also to the polysilicon gate which forms the gate region of the P channel MOS transistor of a peripheral circuit in this case.

Similarly, an N type impurity with low concentration is implanted to the source/drain region of an N channel MOS transistor, and the first impurity layer is formed. A mask is concretely covered to regions other than an N channel MOS transistor of a memory array. Implantation of the arsenic (As) of about 0.5 E+15˜1 E+15 atoms/cm² is done to the first impurity layer that forms the source/drain region of the N channel MOS transistor of a memory array. Implantation of the arsenic (As) of about 0.5 E+15˜1 E+15 atoms/cm² is done also to the polysilicon gate which forms the gate region of the N channel MOS transistor of a memory array in this case.

Next, a mask is covered to regions other than an N channel MOS transistor of a peripheral circuit. Implantation of the arsenic (As) of about 0.5 E+15˜1 E+15 atoms/cm² is done to the first impurity layer that forms the source/drain region of the N channel MOS transistor of a peripheral circuit. Implantation of the arsenic (As) of about 0.5 E+15˜1 E+15 atoms/cm² is done also to the polysilicon gate which forms the gate region of the N channel MOS transistor of a peripheral circuit in this case.

After depositing a silicon oxide film all over a wafer, the case where the silicide wall of an oxide film is formed in the side wall of a polysilicon gate by etching of anisotropy is shown in FIG. 11E. And next, a P type impurity with high concentration is implanted to the source/drain region of a P channel MOS transistor, and the second impurity layer is formed.

A mask is concretely covered to an N channel MOS transistor region. Implantation of the boron or boron fluoride (B or BF₂+) of about 3 E+15˜4 E+15 atoms/cm² is done to the second impurity layer that forms the source/drain region of a P channel MOS transistor. Implantation of the boron or boron fluoride (B or BF₂+) of about 3 E+15˜4 E+15 atoms/cm² will be done also to the polysilicon gate which forms the gate region of the P channel MOS transistor of a memory array in this case.

Similarly the N type impurity whose concentration is high to the source/drain region of an N channel MOS transistor is implanted, and the second impurity layer is formed. Concretely, implantation of the arsenic (As) of about 1 E+15˜4 E+15 atoms/cm² is done to the second impurity layer that forms the source/drain region of an N channel MOS transistor, covering a mask to the region of a P channel MOS transistor.

With the method concerned, a P type impurity is not implanted according to the step of FIG. 11C to the polysilicon gate of the P channel MOS transistor of a memory array. By this, to the polysilicon gate of the P channel MOS transistor of a peripheral circuit, implantation of the boron or boron fluoride (B or BF₂+) of about 5 E+15˜8 E+15 atoms/cm² will be done. However, to the polysilicon gate of the P channel MOS transistor which forms the SRAM memory cell of a memory array, implantation of the boron or boron fluoride (B or BF₂+) of about 3 E+15˜4 E+15 atoms/cm² will be done. Therefore, it is possible to change the implantation concentration of a P type impurity.

That is, in the polysilicon gate of an N channel MOS transistor, in a memory array, the impurity of an N type is implanted like the N channel MOS transistor of a peripheral circuit. However, in the polysilicon gate of the P channel MOS transistor of a memory array, implantation concentration is reduced rather than the polysilicon gate of the P channel MOS transistor of a peripheral circuit.

Hereby, in a PN-junction region, the impurity of a P type is reduced regarding a shared polysilicon gate, for example, the polysilicon gate of transistor NQ1 and PQ1, to the SRAM memory cell of a memory array mentioned above. Therefore, the polysilicon gate of transistor NQ1 cannot receive the influence from the polysilicon gate of transistor PQ1, but can suppress the characteristics variation accompanying gate mutual diffusion in transistor NQ1.

In transistor PQ1 which is a P channel MOS transistor, it is possible that it becomes easy to be influenced by the N type impurity from N channel MOS transistor NQ1 conversely, and threshold value voltage rises under the influence of the formation of gate electrode depletion. However, when threshold value voltage rises, it is possible to cope with it by suppressing a threshold value by the channel implantation for threshold value adjustment.

Therefore, in Embodiment 2 of the present invention, the P type impurity quantity implanted to the gate electrode of the P channel MOS transistor of a memory array is reduced as compared with the P channel MOS transistor of a peripheral circuit. Hereby, the characteristics variation accompanying the gate mutual diffusion of the N channel MOS transistor of a memory array can be suppressed.

### Modification 1 of Embodiment 2

In above-mentioned Embodiment 2, the method which suppresses characteristics variation by reducing the impurity quantity to a P channel MOS transistor implanted into a polysilicon gate was explained. However, it is also possible to suppress characteristics variation with another method.

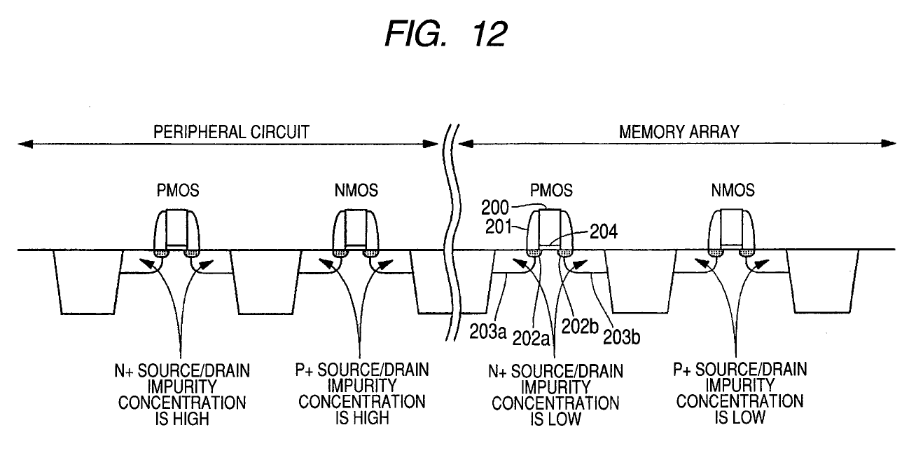

FIG. 12 is a drawing explaining the impurity concentration implanted into the transistor according to modification 1 of Embodiment 2 of the present invention formed in a memory array and a peripheral circuit.

With reference to FIG. 12, as FIG. 10 explained, the P channel MOS transistor and N channel MOS transistor of the SRAM memory cell by which accumulation arrangement is done are shown in the memory array here. The peripheral circuit, concretely the P channel MOS transistor and N channel MOS transistor which forms the circuit for controlling the interior action of a memory array are shown.

In the method according to modification 1 of Embodiment 2 of the present invention, the impurity quantity implanted into the transistor of a memory array is adjusted so that it may become less than the impurity quantity of the transistor of a peripheral circuit.

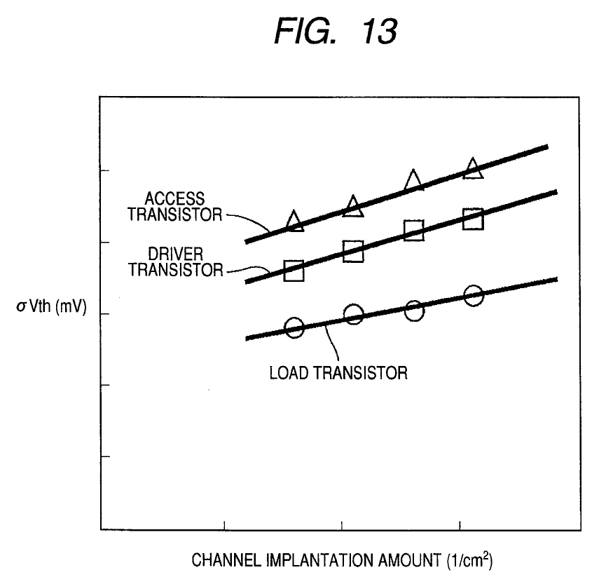

FIG. 13 is a drawing explaining channel implantation amount and the characteristics variation of a transistor.

As shown in FIG. 13, the more channel implantation amount increases, the more it is shown that the characteristics variation of a transistor increases.

Therefore, the characteristics variation of a transistor can be suppressed by reducing the impurity quantity to the transistor of a memory array rather than the transistor of a peripheral circuit.

Here, the threshold value variation of each transistor which forms a SRAM memory cell, concretely an access transistor, a driver transistor, and a load transistor is shown. Since degree of variation of the driver transistor is higher than a load transistor, it is desirable to give priority to the driver transistor and to reduce characteristics variation, as Embodiment 2 explained as it mentioned above. Since the side of the access transistor is higher in the degeree of variation, as it explained by Embodiment 1, it is more desirable than a driver transistor to give priority to the access transistor and to reduce characteristics variation.

### Modification 2 of Embodiment 2

In modification 1 of above-mentioned Embodiment 2, the method which reduces the impurity quantity to the transistor of a memory array rather than the transistor of a peripheral circuit was explained. However, the threshold value voltage of the transistor which forms a peripheral circuit has a common case where many things are formed according to a use.

That is, it is necessary to adjust impurity quantity according to a use also about the transistor of a peripheral circuit.

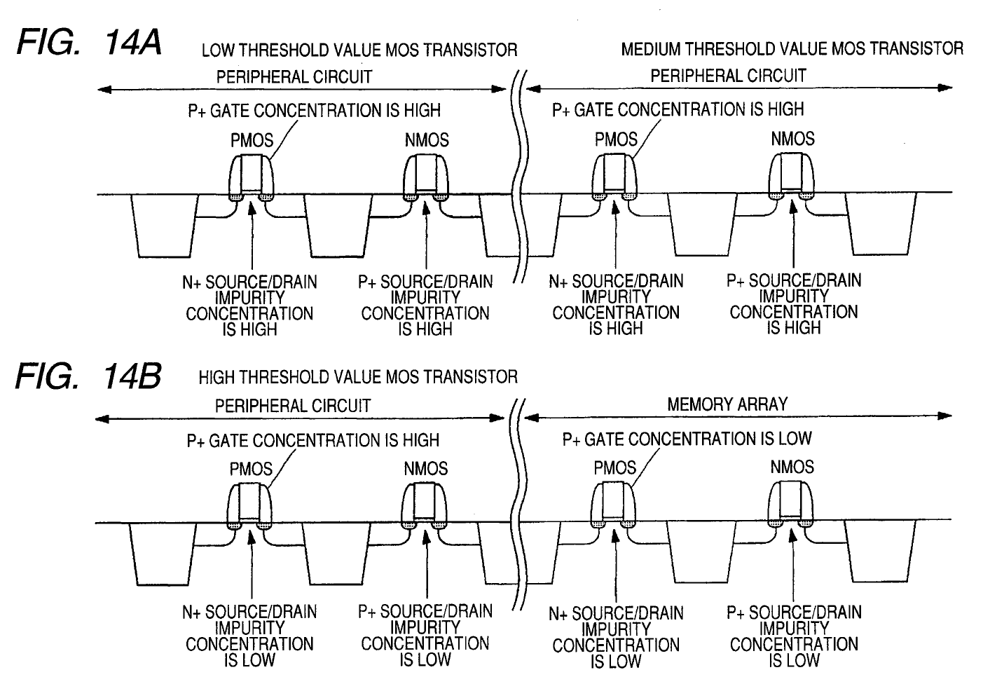

FIGS. 14A and 14B are drawings explaining the impurity concentration implanted into the transistor formed in the memory array and peripheral circuit according to modification 2 of Embodiment 2 of the present invention. Here, the transistor which forms a peripheral circuit and which has three kinds of threshold value voltage is explained as an example.

In FIG. 14A, the transistor of the lowest threshold value voltage (low threshold value MOS transistor), and the transistor of threshold value voltage (medium threshold value MOS transistor) higher threshold value voltage than a low threshold value MOS transistor and lower than the transistor of the highest threshold value voltage (high threshold value MOS transistor) are shown.

The high threshold value MOS transistor mentioned above, and the transistor which forms a memory array are shown in FIG. 14B.

In modification 2 of Embodiment 2 of the present invention, the implantation concentration of an impurity is highly set up about the group of a low threshold value MOS transistor and an medium threshold value MOS transistor. About the group of a high threshold value MOS transistor and the transistor of a memory array, the implantation concentration of an impurity is set up low.

In the step according to FIGS. 11A to 11E, even if it was an MOS transistor of a P type or an N type same in a memory array and a peripheral circuit, the method over which a mask is covered as a separated process, respectively and which performs ion implantation was explained. However, in this example, ion implantation shall be performed as the same step about the portion which can be set as the same step. Concretely, in a peripheral circuit and a memory array, the low threshold value MOS transistor of a peripheral circuit and an medium threshold value MOS transistor are formed at the same step as one group. Similarly, the MOS transistor of a memory array and a high threshold value MOS transistor are formed at the same step as another group.

Hereby, when forming the transistor of a memory array, it becomes possible to implant an impurity simultaneously with formation of a high threshold value MOS transistor, and to form. Therefore, forming is possible to the transistor of a memory array, without adding the special process number which implants an impurity. Hereby, the increase in cost accompanying the increase in a process number can be suppressed.

Since the implantation concentration of an impurity is set up lower than a low threshold value MOS transistor and a medium threshold value MOS transistor, as mentioned above, the increase in the characteristics variation of a transistor can be suppressed. It is also possible to suppress the characteristics variation of a driver transistor by reducing the impurity quantity implanted into a polysilicon gate also about the gate of the P channel MOS transistor of a memory array, as mentioned above. In FIGS. 14A and 14B, the case where there is little impurity quantity to implant is shown as an example about the P channel MOS transistor of the memory array as compared with the polysilicon gate of the P channel MOS transistor of the transistor of other peripheral circuits. That is, the impurity concentration (P+ gate concentration) of the polysilicon gate of the P channel MOS transistor of a peripheral circuit is set up highly, and the impurity concentration (P+ gate concentration) of the polysilicon gate of the P channel MOS transistor of a memory array is set up low.

### Embodiment 3

In the above-mentioned embodiment, the method which suppresses the characteristics variation of a transistor was explained in connection with microfabrication. Generally according to microfabrication, it becomes difficult to secure the writing and read-out margin of a SRAM memory cell.

In Embodiment 3, the method which secures the writing and read-out margin of a SRAM memory cell is explained.

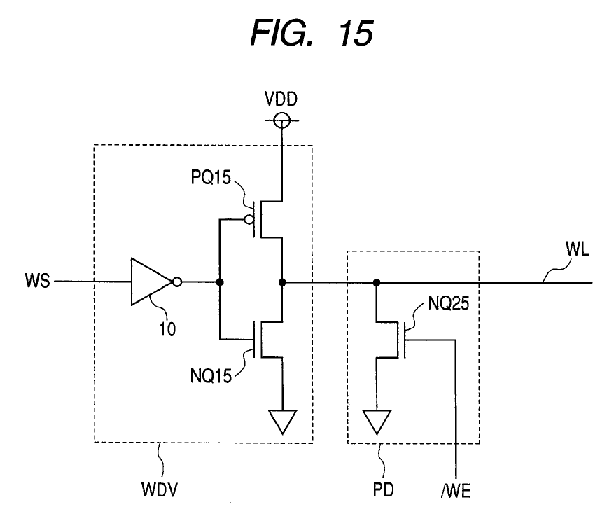

FIG. 15 is a schematic diagram of word line driver WDV and assistant circuit PD according to Embodiment 3 of the present invention.

With reference to FIG. 15, word line driver WDV includes inverter 10 which receives word line selection signal WS from row decoder 2, and P channel MOS transistor PQ15 and NQ15 which forms the CMOS inverter which reverses the output signal of inverter 10 and drives word line WL.

At the time of selection of word line WL, word line selection signal WS is H level, it responds, the output signal of inverter 10 constitutes L level, P channel MOS transistor PQ15 conducts, and supply voltage VDD from a power node is transmitted to word line WL.

It connects between a word line and a ground node, and assistant circuit PD includes N channel MOS transistor NQ25 which receives complementary write-in indication signal/WE in a gate.

Complementary write-in indication signal/WE are generated from main control circuit 7 shown in FIG. 1, and the structure of the whole semiconductor memory device in Embodiment 3 of this invention is the same as the structure shown in FIG. 1.

Complementary write-in indication signal/WE are generated from write-in indication signal WE, constitutes H level at the time of data read mode, and constitutes L level at the time of data write.

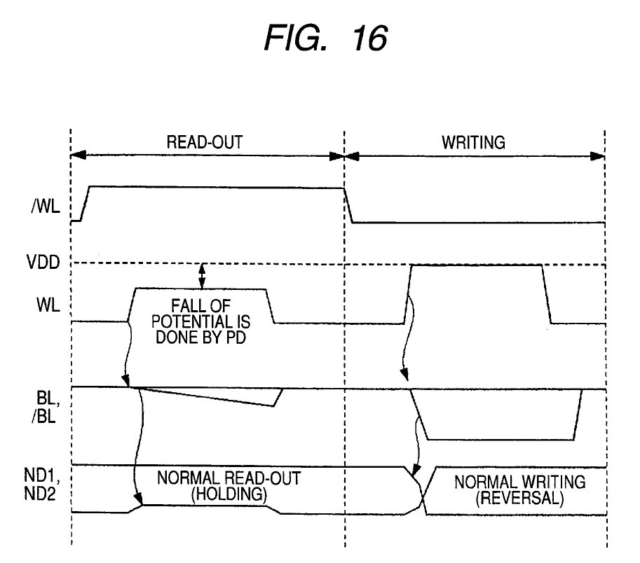

FIG. 16 is a drawing showing the signal wave form of the main nodes at the time of read-out and the writing of the data at the time of using pulldown element PD shown in FIG. 15. Complementary write-in indication signal/WE will be set as H level at the time of data read-out, and N channel MOS transistor NQ25 will be in continuity in pulldown element PD. Therefore, selection word line WL drives to the voltage level determined by the ratio of the on resistance of P channel MOS transistor PQ15 of the drive stage in word line driver WDV to the on resistance of N channel MOS transistor NQ25 for this pulldown. When the voltage of word line WL is low, the conductance of an access transistor becomes small. Resistance between memory node ND1 and ND2 inside a memory cell and a bit line becomes large by this. The lift of the electric potential of internal memory node ND1 and ND2 is suppressed (the pull-up of the memory node by the access transistor at the time of word line selection becomes weak). Therefore, even if the voltage level of internal memory node ND1 or ND2 rises according to column current (bit line current), a read-out margin (static noise margin SNM) can fully be secured, data can be held stably, and data can be read, without generating data corruption.

On the other hand, complementary write-in indication signal/WE are set as L level at the time of data write, and N channel MOS transistor NQ25 for pulldown will be in non-continuity. Therefore, word line WL is driven to a supply voltage VDD level in this case by P channel MOS transistor PQ15 for charge of word line driver WDV at the time of selection. Therefore, the voltage level of word line WL is made high at the time of data write, a write-in margin becomes high, and data can be written in at high speed.

Therefore, by stopping pulldown operation of assistant circuit PD at the time of data write, the word line voltage level at the time of data write can be set even to a source voltage level, and it can prevent that the margin at the time of writing deteriorates and the write-in defect of data occurs. Hereby, in any case of data read-out and writing, a margin can fully be secured and writing/read-out of data can be performed stably.

As mentioned above, according to the structure according to Embodiment 3 of the present invention, it forms so that assistant circuit PD may be stopped at the time of data write, and lowering of the voltage level of the selection word line at the time of data write can be suppressed. The voltage level of a selection word line can be reduced at the time of data read-out, the margin of read-out of data and writing can fully be secured, and writing/read-out of data can be performed stably.

With all the points, the embodiment disclosed this time is exemplification and should be considered not to be restrictive. The range of the present invention is shown by the above-mentioned not explanation but claim, and it is meant that an equal meaning and all the change in within the limits as a claim are included.

What is claimed is:

1. A semiconductor memory device, comprising:
a memory array which has a plurality of memory cells arranged at matrix form;
a word line formed corresponding to a memory cell row; and
a bit line pair formed corresponding to a memory cell column;
wherein
the each memory cell includes a first inverter including a first N-channel MOS transistor and a first P-channel MOS transistor, a second inverter including a second N-channel MOS transistor and a second P-channel MOS transistor, and a third and a fourth N-channel MOS transistor;
an input node of the first inverter is connected to an output node of the second inverter so that the first inverter and the second inverter may form a flip-flop, and an input node of the second inverter is connected to an output node of the first inverter;
the third N-channel MOS transistor is connected between one side of a corresponding bit line pair, and an input node of the second inverter, and a gate is electrically combined with a corresponding word line;
the fourth N-channel MOS transistor is connected between the other of the corresponding bit line pair, and an input node of the first inverter, and a gate is electrically combined with the corresponding word line;
the each memory cell includes a first active region that forms the first and the third N-channel MOS transistor formed over a substrate, a second active region that forms the second and the fourth N-channel MOS transistor, and the first to the fourth polysilicon wiring that are formed respectively corresponding to the first to the fourth N-channel MOS transistor, and that are located so that a corresponding active region may be crossed, and form the channel region specified with channel length and channel width;
in the first active region, the third N-channel MOS transistor is designed more greatly than at least one of the channel length and channel width of the first N-channel MOS transistor, and threshold value voltage of the first N-channel MOS transistor is designed low rather than the third N-channel MOS transistor originating in the channel length and channel width; and
in the second active region, the fourth N-channel MOS transistor is designed more greatly than at least one side of the channel length and channel width of the second N-channel MOS transistor, and threshold value voltage of the second N-channel MOS transistor is designed low rather than the fourth N-channel MOS transistor originating in the channel length and channel width.

2. A semiconductor memory device according to claim 1, further comprising:
a word line driver which drives a word line corresponding to a memory cell row; and
an assistant circuit which drops a voltage level of a word line driven with the word line driver chosen at a time of data read-out to prescribed voltage.

3. A semiconductor memory device, comprising:
a memory array which has a plurality of memory cells arranged at matrix form; and
a peripheral circuit for interior-action control of the memory array;
wherein
the each memory cell formed by a first inverter including a first N-channel MOS transistor and a first P-channel MOS transistor, and a second inverter including a second N-channel MOS transistor and a second P-channel MOS transistor connected so that a flip-flop may be formed with the first inverter includes a first and a second active region that forms the first and the second N-channel MOS transistor, respectively, and a third and a fourth active region that forms the first and the second P-channel MOS transistor which are formed over a substrate in order to form the first and the second inverter, a first polysilicon wiring that is located so that the first and the third active region may be crossed, and forms a gate region of the first N-channel MOS transistor and P-channel MOS transistor, and a second polysilicon wiring that is located so that the second and the fourth active region may be crossed, and forms a gate region of the second N-channel MOS transistor and P-channel MOS transistor; and
an impurity quantity implanted into a gate region of the first and the second P-channel MOS transistor is set up less than an impurity quantity implanted into a gate region of the P-channel MOS transistor formed in the peripheral circuit.

4. A semiconductor memory device, comprising:
a memory array which has a plurality of memory cells arranged at matrix form; and
a peripheral circuit for interior-action control of the memory array
wherein
the each memory cell includes a plurality of MOS transistors which form a first inverter and a second inverter connected with the first inverter so that a flip-flop may be formed;
the each MOS transistor includes an active region which has an impurity implantation region formed over a substrate; and
an impurity quantity implanted into an impurity implantation region of each of the MOS transistor of the memory array is set up less than an impurity quantity implanted into an impurity implantation region of a MOS transistor formed in the peripheral circuit.

5. A semiconductor memory device, comprising:
a memory array which has a plurality of memory cells arranged at matrix form; and
a peripheral circuit for interior-action control of the memory array;
wherein
the each memory cell includes a plurality of MOS transistors which form a second inverter connected with a first inverter so that a flip-flop may be formed with the first inverter;
the each MOS transistor includes an active region which has an impurity implantation region formed over a substrate;
the peripheral circuit includes a first group's MOS transistor group which has a first threshold value voltage, and a second group's MOS transistor group which has a second threshold value voltage higher than the first threshold value voltage; and
an impurity quantity implanted into an impurity implantation region of each of the MOS transistor of the memory array is set up few rather than an impurity quantity implanted into an impurity implantation region of the first group's MOS transistor group formed in the peripheral circuit, and it is set up like an impurity quantity implanted into an impurity implantation region of the second group's MOS transistor group.
